(19) United States
(12) Patent Application Publication
(10) Pub. No.: US 2001/0008287 A1
(43) Pub. Date: Jul. 19, 2001

(54) Photodetector and a method to manufacture it

(75) Inventors: Karsten Kraiczek, Waldbronn (DE); Hubert Kuderer, Waldbronn (DE)

Correspondence Address: LOWE HAUPTMAN GILMAN & BERNER, LLP, Suite 310, 1700 Diagonal Road, Alexandria, VA, 22314, US

(73) Assignee: AGILENT TECHNOLOGIES, INC.

(21) Appl. No.: 09/758,315

(22) Filed: Jan. 12, 2001

(30) Foreign Application Priority Data
Jan. 15, 2000 (DE) 100 01 498.4

(51) Int. Cl. H01L 31/0328

(52) U.S. Cl. 257/186

(57) ABSTRACT

The invention concerns a photodetector for detecting electromagnetic waves, especially in the UV range, and a method of forming it. The photodetector has at least one substrate layer consisting essentially of silicon. The substrate layer has a surface that is (1) at least partially covered with a cover layer transparent to electromagnetic waves and (2) covered by a cover layer surface. The cover layer has an essentially saw-tooth, trapezoidal and/or V-shaped in a cross-sectional cut through the substrate layer and the cover layer thickness is inhomogeneous.

### FIELD OF THE INVENTION

The invention concerns a photodetector for detecting electromagnetic waves, especially in the UV range, and a method to manufacture it, wherein the photodetector includes at least one substrate layer (e.g., consisting of silicon) with a substrate surface, and at least one cover layer with a cover layer surface that at least partially covers the substrate surface and is transparent to electromagnetic waves.

### BACKGROUND ART

Photodetectors such as silicon photodiodes are usually covered with a thin, reflection-reducing layer, typically made of silicon dioxide. This cover layer essentially serves as a protective layer against undesirable environmental influences such as the inward diffusion of moisture and/or mobile particles or foreign atoms that can soil the substrate layer of the photodetector that essentially consists of silicon. The thicker the protective layer(s), the more effective the protection. Experimental investigations have shown that the thickness of the protective layers substantially influences the level and spectral curve of the reflection strength. Depending on the layer thickness and/or wavelength, undesirable interference patterns can arise, i.e., fluctuations or oscillations of the reflection values. The number of fluctuations or oscillations greatly rises with the layer thickness and/or with decreasing wavelength. Hence, particularly when the protective layers are very thick and/or the wavelengths are short, very slight changes in the layer thickness within the range of a few hundredths of a micrometer can produce wide fluctuations in the reflection values. In addition, the photodetector becomes sensitive to spectral shifts, especially in the UV range. When the layers are thick (which is preferred for the better protection), substantial interference arises. The layers also differ from instrument to instrument because presently feasible and economically acceptable manufacturing tolerances cannot be further reduced.

For these reasons, the oxide layer thickness of approximately 0.1 micrometers is generally sought in silicon photodiodes. This substantially reduces undesirable indifference structure. However the oxide layer that grows to more than 1 micrometer during the process must be etched away when manufacturing photodiode cells using CMOS technology. This additional step is involved and undesirable, and the layer thickness tolerances are relatively large depending on the manufacturing effort. In addition, an oxide layer reduced to 0.1 micrometers also reduces the protection and shortens the length of use or life of the photodetector. For these reasons, an oxide layer of approximately 1-2 micrometers that arises in the standard procedure is favored in conventional CMOS processes.

U.S. Pat. No. 4,277,793 discloses a photodetector having a substrate layer with at least one cover layer having a surface at least partially covering a surface of the substrate, wherein the cover layer is transparent to the electromagnetic waves to be detected. This prior art photodetector has a p-doped or n-doped semiconductor substrate layer that has recesses with a semicircular cross-section that form a wave-like surface structure. The recesses are created with an isotropic etching procedure and can be coated with an anti-reflex silicon monoxide coating. The resulting cross-sectional surface structure corresponds to that of the semiconductor substrate layer so that the anti-reflex coating has a homogeneous cross-section, i.e., even surface thickness. The semicircular recesses or the wave-like surface structure reduce the back reflection and increase the optical path length and the photosensitivity when the detector is used in the long-wave range. The undesirable interference pattern or oscillations of the reflection strength and increased photodetector sensitivity to spectral shifts can still arise, however.

Such photodetectors are used, for example, in a spectrophotometer or in a diode array detector of a liquid chromatography system. In such an application, the above-mentioned aspects regarding oxide layer thickness and its effects are particularly important.

On the one hand, it is desirable to increase the protection and thus the reliability of the photodetector by using a thick oxide layer, particularly when using it in environments contaminated with aggressive chemicals; on the other hand, it would be preferable to have a thin oxide layer in view of the effects of spectral shifts on the measuring result.

Spectral shifts are due to effects in a flow cell through which liquids are flowing. Such effects are causes by flow rate changes and the corresponding influences on the flow behavior, or by refractive index changes due to composition changes of the solvent (eluent), or by sample substances in the flow cell. Furthermore, shifts in optical components can be caused, for example, by thermal expansion or by humidity.

The effects of the spectral shift on the measuring result is due to the occurrence of the above-mentioned oscillations in the spectral reflection characteristics as a function of the oxide layer thickness. The number of oscillations increases with increasing oxide layer thickness. As a result, the spectral sensitivity characteristics have very steep slopes. It can easily be understood that, due to small but unavoidable spectral shifts, great output signal variations are thereby caused during operation of such diode array detectors. The magnitude of these unwanted output signal variations is directly correlated with the frequency of the oscillations which in turn is dependent on the selected oxide layer thickness. This means that the influence on and the distortion of the measuring results are highly dependent on the oxide layer thickness. Therefore, it would be desirable to select a thin oxide layer which does not require a large layer thickness for protective purposes.

It is therefore the object of the invention to eliminate interference from oscillations in the reflection strength of photodetectors of the initially-cited type independent of the cover layer thickness with a favorable photosensitivity, especially in the UV range.

### SUMMARY OF THE INVENTION

This object is attained by providing the cover layer with an inhomogeneous thickness and a sloping side in a cross-sectional cut through the substrate layer. The cover layer sloping side is preferably essentially a saw-tooth, trapezoidal and/or V-shaped design in the cross-sectional cut. By providing a sufficient amount of inhomogeneity in the cover layer thickness, especially the oxide layer in a photodiode element, the reflection values can be “mixed” independently of the cover layer thickness so that the undesirable indifference structure or oscillations can be avoided, particularly with thick cover layers. Thus thick oxide layers can be easily created to yield particularly effective protection.

The substrate layer is advantageously provided with at least one recess, and/or the cover layer has at least one elevation. The arising multiple reflections also reduce the reflection and increase the optical sensitivity of the photodetector, especially in the UV range. Such recesses and/or elevations can be easily manufactured, e.g. by anisotropic etching. The material properties and material structure of the substrate layer essentially made of silicon allow the particularly precise and reproducible manufacture of the recesses in the substrate layer and hence the distribution of the oxide layer thickness or inhomogeneity of the cover layer thickness.

The recess and/or elevation are usefully pyramidal. Such a three-dimensional structure is particularly advantageous and reproducible for cover layers of silicon dioxide and especially for substrate layers essentially consisting of silicon, especially using an anisotropic etching procedure. In addition, the above-cited measures allow the number of multiple reflections to be further increased to additionally improve the optical sensitivity of the photodetectors.

The measures are particularly advantageous when the recess and/or elevation has at least one flank with an essentially straight cross-section. This creates a cover layer thickness distribution where all cover layer thicknesses are equally distributed, i.e., occur with the same frequency. Under these prerequisites, a particularly favorable “mixture” of the reflection values can be attained so that disturbing interference or oscillations of the reflection values or output signals of the photodetector can be avoided independently of the cover layer thickness.

The invention is particularly advantageous when the substrate layer has at least one recess that contains at least one flank with a cross-section that is essentially straight, and the cover layer surface is essentially flat. This preferred variation allows a particularly advantageous recess manufacturing method and cover layer application, and the distribution of the cover layer thickness is precise and easy to reproduce.

The essentially flat flank usefully forms an angle greater than 45° with the cover layer surface, and preferably greater than or equal to 54.7°. The last-cited angle is particularly advantageous due to the crystal structure of the substrate layer essentially consisting of silicon. If there are a large number of flanks, i.e., recesses with sloped surfaces, the number of reflections and hence the optical sensitivity can be further increased.

The invention is also useful when at least two flanks oppose each other at an angle that is preferably less than 90°, and especially less than or equal to 70.6°. This measure, and especially the provision of numerous flanks, allows the reflection values and optical sensitivity of the photodetectors to be further improved.

The invention is particularly advantageous for applications in a wavelength range of 200-800 nanometers, in which case the thickness of the cover layer has an absolute inhomogeneity (i.e., independent of the overall thickness of the cover layer) of 0.5 micrometers, and preferably 1 micrometer. This apparently simple measure surprisingly revealed that disturbing interference from oscillations in the reflection strength or oscillations in the output signals of the photodetectors can be prevented independently of the total value of the cover layer thickness, particularly in the UV range and preferably in a wavelength range of 200-800 nanometers.

To manufacture a photodetector of the initially-cited type for detecting electromagnetic waves, the substrate layer is preferably provided with at least one recess using an anisotropic etching method and is subsequently filled with the cover layer so that the cover layer has an essentially saw-tooth, trapezoidal and/or V-shaped design in a cross-sectional cut through the substrate layer, and the cover layer thickness is inhomogeneous. When anisotropic etching procedures are used to create the recesses, saw-tooth, trapezoidal and/or V-shaped recesses are particularly easy to create in the substrate layer essentially made of silicon that can be advantageously filled with the cover layer.

Advantageously, at least one recess is completely filled with the cover layer and the substrate surface is completely covered to form an essentially flat cover layer surface.

This allows the particularly favorable, reproducible and precise manufacture of the advantageous cover layer distribution. It can also be useful to further planarize the cover layer surface by mechanical, chemical, physical and/or other suitable means.

A particularly good and easy manufacturing method is to apply the cover layer as a liquid or highly-viscous material onto the substrate layer, preferably by a glass spin-on method.

It is also particularly advantageous for the substrate layer surface to be essentially flat before at least one recess is provided, and to be preferably provided with at least one recess before semiconductor-forming steps are carried out. With this method (that can also be termed pre-processing), particularly precise and reproducible cover layer thickness distributions can be realized by directly providing the original very flat substrate layer of the silicon wafer with the recesses. The recesses are preferably created using an anisotropic etching procedure, and they have a saw-tooth, trapezoidal and/or V-shaped cross-section in the plane perpendicular to the highly-planar substrate surface of the silicon wafer. Due to the crystal structure of the silicon substrate, highly-precise and reproducible flat flanks can be created. The recesses can be advantageously filled and/or coated with silicon dioxide, e.g. using thermal methods or the above-described preferred methods.

Both by themselves or together, the above measures contribute to the creation of photodetectors where interference from oscillations in the reflection strength or oscillations in the output signals of the photodetectors can be prevented independent of the cover layer thickness with good photosensitivity, particularly in the UV range.

Other features, perspectives and advantages of the invention can be found in the following descriptive section that refers to the figures.

The above and still further objects, features and advantages of the present invention will become apparent upon consideration of the following detailed descriptions of several specific embodiments thereof, especially when taken in conjunction with the accompanying drawings.

### BRIEF DESCRIPTION OF THE DRAWING

FIG. 1 is a highly-enlarged schematic cross-section of a first preferred embodiment of a photodetector of the invention along the line 1-1, FIG. 3, with the recesses in the shape of a frustum of a pyramid in the substrate layer with edges that are trapezoidal or V-shaped in a cross-sectional cut;

FIG. 2 is an enlarged schematic cross-section of another exemplary embodiment of a photodetector, wherein the substrate layer surface is flat, and elevations in the shape of a frustum of a pyramid are in the cover layer that have trapezoidal or V-shaped edges in the portrayed cross-section;

FIG. 3 is an enlarged top view of the photodetector illustrated in FIG. 1, with recesses in the substrate layer in the shape of a frustum of a pyramid in a regular matrix;

FIG. 4 is an enlarged top view of another exemplary embodiment of a photodetector with V-shaped recesses in the substrate layer extending in the lengthwise direction of the photodetector;

FIG. 5 is an enlarged top view of another exemplary embodiment of a photodetector with V-shaped recesses in the substrate layer extending in the transverse direction of the photodetector;

FIG. 6 includes reflection curves of pure silicon and a silicon photodetector coated with silicon dioxide according to prior art and according to one embodiment of the invention; and

FIG. 7 includes the instrument profiles of silicon photodetectors in the form of photodiode arrays according to the prior art and according to one embodiment of the invention.

### DETAILED DESCRIPTION OF THE DRAWING

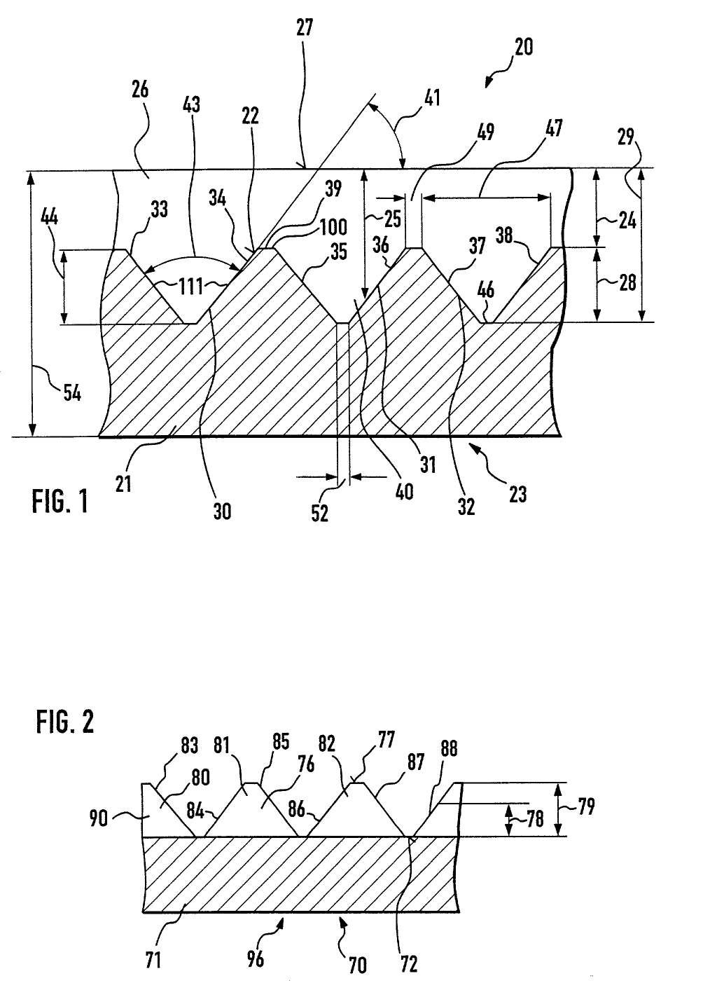

The photodetector 20 in FIG. 1 is preferably used in a spectrometer for analyzing the spectral composition of electromagnetic waves, usually in the UV spectrum, from a sample flowing through a sample cell. In one arrangement, a UV polychromatic source irradiates the sample which partially absorbs waves from the sample to affect the waves incident on photodetector 20 to provide an absorbance detector. In another arrangement, the sample emits the UV waves photodetector 20 detects, to provide a fluorescence detector.

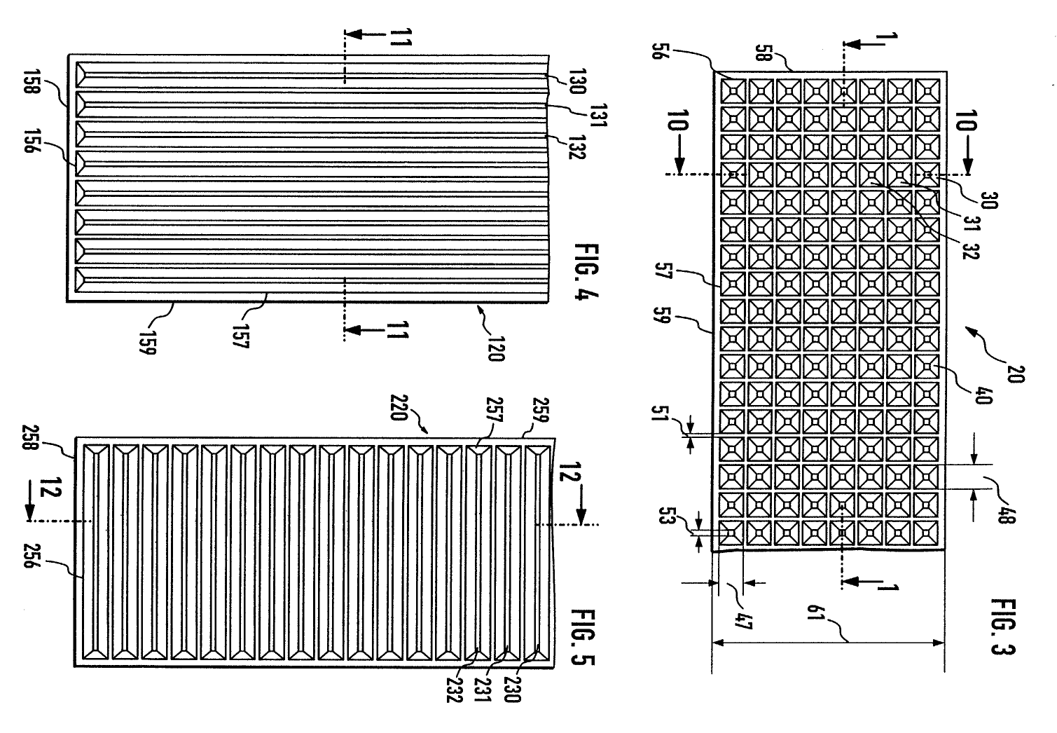

Photodetector 20 has a substrate layer 21 of a <100>plane oriented silicon wafer whose substrate surface is completely covered with the cover layer 26 made of silicon oxide. This has a flat cover layer surface 27. The substrate layer 21 is provided with recesses 30, 31, 32, in the shape of truncated pyramids that has the trapezoidal or V-shaped edges in the cross-section 23 in FIG. 1 perpendicular to the cover layer surface 27. The angled edges form essentially straight flanks 33, 34, 35, 36, 37, 38. The flanks 33, 34, 35, 36, 37, 38 of recesses 30, 31, 32 correspond to the line of intersection of the <111>plane oriented crystal planes of the <100>plane oriented silicon wafer substrate layer. Each flank 33, 34, 35, 36, 37, 38 forms an angle 41 with the flat cover layer surface 27 that is approximately 54.7° in this case. Due to the truncated pyramid shape of the recesses 30, 31, 32, every two of the flanks 33, 34; 35, 36; 37, 38 oppose each other at an angle 43 that is approximately 70.6° in this case. Recesses 30, 31, 32 are designed and arranged in the exemplary embodiment so that there is a top frustum surface 39 horizontal or parallel to the cover layer surface 27 and a bottom frustum surface 46 between the opposing flanks 33, 34; 35, 36; 37, 38. The top frustum surface 39 has segment width 49, and the bottom frustum surface 46 has peak width 52. Ideally, segment width 39 and peak width 52 are as small as possible, i.e., around zero to provide a linear thickness distribution of the cover layer thickness 28; each cover layer thickness occurs with the same frequency or is evenly distributed viewed along the substrate surface 22. This yields the best “mixed results” in view of suppressing or preventing interference and oscillations of the reflection values or output signals of the photodetector 20. It is theoretically sufficient for the photodetector 20 to have a ramp-like, linearly ascending or descending cover layer thickness that runs in a single direction, preferably the entire width 61 (FIG. 3) or length. To attain the highest optical sensitivity, i.e., the greatest photon yield and not have to go too deep in the substrate, it is desirable to have the largest number of recesses 30, 31, 32 and steepest angle 41 or 43.

The recesses 30, 31, 32, designed as a frustum of a pyramid 40, have a base width 47 that is preferably 1-5 micrometers.

The cover layer 26 has a maximum thickness 29 that is preferably approximately 2 micrometers. As can be clearly seen in FIG. 1, the cover layer 26 in the shown cross-section 23 is trapezoidal or V-shaped and has an inhomogeneous cover layer thickness 25. In the areas above top frustum surface 39 and the bottom frustum surface 46, the cover layer 26 has a constant cover layer thickness 24 or 29 that corresponds to the minimum and maximum value of the cover layer thickness. In the area of flanks 33, 34, 35, 36, 37, 38 of recesses 30, 31, 32, the constant cover layer thickness 24 superposes a linear rising or falling section of the cover layer thickness that attains a maximum value corresponding to the cover layer thickness 28. The maximum cover layer thickness 29 results from the sum of the minimum cover layer thickness 24 and cover layer thickness 28.

The inhomogeneity of the cover layer 26 corresponding to cover layer thickness 28 (that has a linear cover layer thickness distribution in the exemplary embodiment between zero and the maximum value corresponding to cover layer thickness 28) is preferably 0.5 micrometers, especially 1 micrometer, and the photodetector 20 typically has an overall height or thickness 54 that is approximately 0.5-2 mm.

With such a variation in the absolute cover layer thickness distribution, the interference, i.e., oscillations of the reflection values or output signals of the photodetector, can be prevented in a particularly favorable manner.

FIG. 2 shows another exemplary embodiment of a photodetector 70. In contrast to the above-described exemplary embodiment, an inhomogeneous cover layer thickness 78 is attained in this case by providing elevations 80, 81, 82 in the cover layer 76. The photodetector 70 has a substrate layer 71 with the flat substrate surface 72. On the substrate surface 72 are the elevations 80, 81, 82 of the cover layer 76 designed as the frustum of a pyramid 90. In the cross-section 96 in FIG. 2 perpendicular to the cover layer surface 77, the elevations 80, 81, 82 have essentially straight flanks 83, 84, 85, 86, 87, 88. The flanks 83, 84; 85, 86; 87, 88 oppose each other in sets of two at an angle that is preferably less than 90°. In contrast to the exemplary embodiment in FIG. 1, the inhomogeneous cover layer thickness 78 of the cover layer 76 in the variation in FIG. 2 is attained solely by a variation of the cover layer thickness 79 of the cover layer 76.

Of course the designs in FIG. 1 and 2 can be combined to attain the inhomogeneous cover layer thickness according to the invention. The geometric structure of the substrate layer and that of the cover layer can be harmonized with each other to attain an inhomogeneous cover layer thickness of the cover layer. Of course, the substrate layer 21 can be provided with elevations and/or the cover layer can be provided with recesses for this purpose.

FIG. 3 shows the photodetector 20 from FIG. 1 in a top view in which the regular matrix-like arrangement of the recesses 30, 31, 32 shaped as pyramid frustums 40 can be clearly seen. The recesses 30, 31, 32 each have parallel width edges 56 and parallel depth edges 57 perpendicular to the width edges, whereby the width edge 56 has a base width 47, and the depth edge 57 has a base depth 48. The width edges 56 and the depth edges 57 are preferably parallel to the transverse edges 58 or the lengthwise edges 59 of the photodetector 20 as shown in FIG. 3 so that the width edges 56 and depth edges 57 are always parallel to specific crystal planes corresponding to the crystal orientation in the substrate layer of the silicon wafer. This makes particularly good use of the area and permits a maximum number of sloped surfaces or flanks to the recesses 30, 31, and 32. The width 61 of the photodetector 20 is preferably 25 micrometers for photodiode arrays, and up to a few millimeters for photodiodes. The cross-section 23 of the photodetector identified in FIG. 3 with line of intersection 1-1 and the lengthwise cross-section identified in FIG. 3 as line of intersection 10-10 correspond to the cross-section 23 in FIG. 1.

FIG. 4 shows another exemplary embodiment of a photodetector 120. This has parallel trapezoidal or V-shaped recesses 130,131, 132 in the lengthwise direction or parallel to the lengthwise edges 159 of the photodetector 120. The cross-sectional arrangement and shape of the recesses 130, 131, 132 that result from the cross-section indicated by section 11-11 in FIG. 4 correspond to the situation in FIG. 1.

Another exemplary embodiment of a photodetector 220 is shown in FIG. 5. This is designed similar to the photodetector 120 with the recesses 230, 231, 232 with a trapezoidal or V-shaped recess cross-section. In contrast, the recesses 230, 231, 232 of the photodetector 220 are perpendicular to the lengthwise axis of the photodetector 220 so that the width edges 256 of the recesses 230, 231, 232 are parallel to the transverse edge 258 of the photodetector 220, or the depth edges 257 of the recesses 230, 231, 232 are parallel to the lengthwise edge 259 of the photodetector 220. The cross-section of the photodetector 220 along lines of intersection 12-12 in FIG. 5 corresponds to the cross-section in FIG. 1.

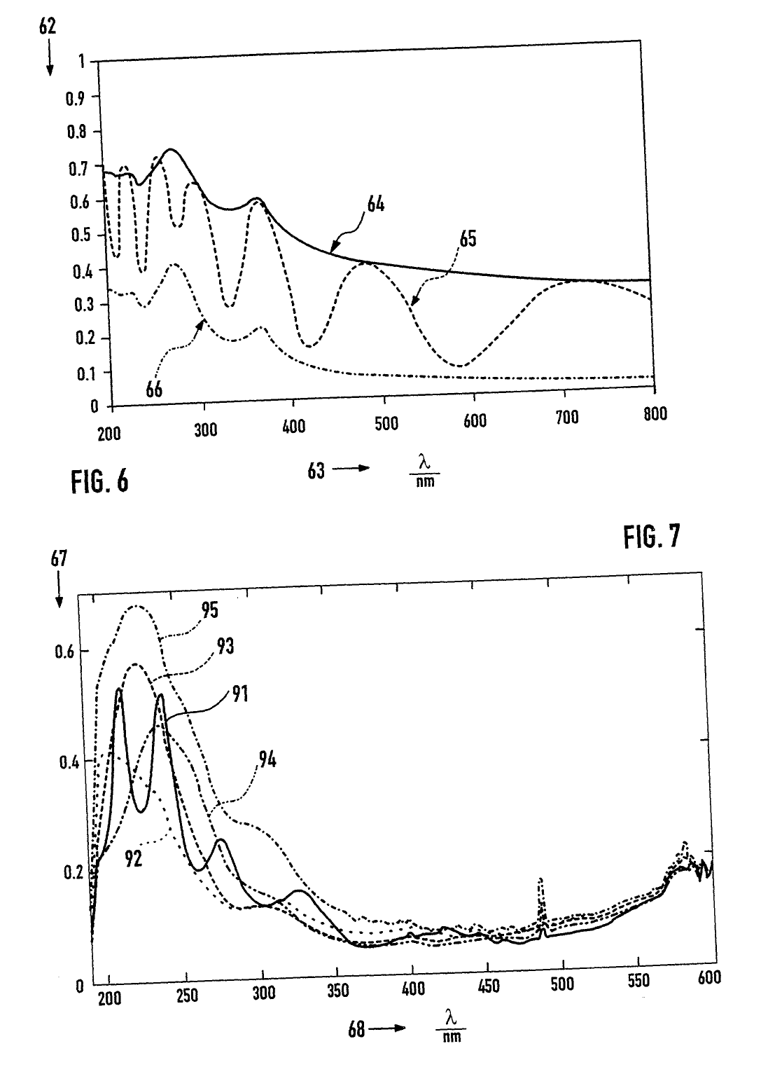

FIG. 6 shows the reflection curves, i.e., the reflection strength of pure silicon (plotted as a function of the wavelength) and of a silicon photodetector covered with silicon dioxide according to the state-of-the-art and the invention. In comparison to the reflection curve 64 of pure silicon, the reflection curve 65 of a photodetector with a state-of-the-art, 0.5-micrometer thick silicon dioxide layer has strong oscillations in the reflection strength 62. As can also be easily seen in FIG. 6, the number of oscillations increases as the wavelength decreases. In contrast, the characteristic reflection curve 66 attained with the photodetector according to the invention with an inhomogeneous cover layer thickness is nearly identical with that of the reflection curve 64 for pure silicon without any disturbing interference or oscillation in the reflection strength 62. Much lower reflection values are attained due to the design of the sloped flanks of the recesses 30, 31, 32 that allows multiple reflection and due to the “mixture” of the reflection values.

FIG. 7 shows different instrument profiles depending on the dimensions and thickness of the silicon dioxide cover layers where the instrument output signal 67 is plotted against the wavelength 68. An example of the instrument profile 91 of a state-of-the-art silicon photodiode array with a 0.5-micrometer thick cover layer of silicon dioxide clearly shows oscillations in the instrument output signal 67. The steep flanks in the oscillation ranges make the photodetector particularly sensitive to spectral shifts, particularly in the UV range. The instrument profiles 92, 93 and 94 of silicon photodiode arrays covered with silicon dioxide are also plotted in FIG. 7, with cover layers that are 0.08, 0.1 and 0.12 micrometers thick. This illustrates that only a very slight difference in thickness of 0.02 micrometers produces a clear spectral shift of the attainable instrument profiles and clearly different levels of the instrument output signals 67. Silicon wafers that are covered with such a thin homogenous oxide layer thickness can be attained with instrument profiles 67 that are similarly low in interference or are free of interference. However, the required manufacturing effort is substantial. In addition, the above-describe spectral shifts and variations of the level of the instrument output signals can fall within the limits of the economically reasonable manufacturing tolerances. These can also vary from instrument to instrument and require corresponding adaptations to the evaluation electronics of each device. Finally, the state-of-the-art cover layers only have a relatively limited photon yield in connection with a correspondingly limited optical sensitivity of the photodetectors.

In contrast, a photodetector according to the invention produces the instrument profile 95 shown in FIG. 7. No undesirable interference or oscillations of the instrument output signals 67 arises. Additionally, in comparison to the overall state of the art and especially in the UV range, clearly higher values for the instrument output signals 67 can be attained which means a correspondingly higher optical sensitivity of the photodetector.

Of course, the cover layer design according to the invention can be used for more than cover layers made of silicon dioxide. The cover layer can also include other materials such as silicon nitride, and/or several cover layers can be composed of different substances or materials.

The method to manufacture the photodetector according to the invention is now described.

In a first preferred manufacturing method, the substrate layer of a silicon wafer is provided with at least one recess (preprocessed) before the semiconductor-forming steps, such as specific types of doping, etc., are performed. The fact can be advantageously exploited that the substrate surface 22 of the silicon wafer is very flat. If recesses 30, 31, 32 with a precise geometrical arrangement and dimensions are formed in this very flat substrate surface 22 of the substrate layer 21 as described in the following, a particularly precise and exact cover layer thickness distribution of the silicon dioxide cover layer can be attained. This is particularly advantageous for avoiding interference or oscillations of the reflection strength and hence the output signals of the photodetectors, and it produces particularly high optical sensitivity.

In the preprocessing manufacturing step, a layer of silicon dioxide is first placed on the silicon wafer in a conventional manner. Another layer that consists of silicon nitride is applied on top of the silicon dioxide layer. On this silicon nitride layer, a photosensitive layer is applied that is also termed photoresist. This is then illuminated using a mask whose openings are designed corresponding to the dimensions of the perimeter of the recesses to be created. With positive photoresist, the illuminated surface areas are then removed using suitable conventional etching procedures; in the case of negative photoresist, the unilluminated areas are removed. Subsequently or simultaneously, the layers underneath of silicon nitride and silicon dioxide are removed in the areas corresponding to the dimensions of the perimeter of the mask openings. Finally, the substrate layer is provided with at least one recess using an anisotropic etching procedure. Due to the crystalline structure of the used <100>plane oriented silicone wafer, the <100>plane oriented planes are etched away while the <111>crystal planes that are at an angle of approximately 54.7° to the wafer surface are basically not attacked by the etching reagent. This procedure is a particularly good and highly precise way to create the recesses 30, 31, 32 in the shape of the frustum of a pyramid 40. After the recesses 30, 31, 32 in the shape of a pyramid frustum are created, the etching masks made of silicon dioxide and silicon nitride are removed. Then the recesses 30, 31, 32 are filled with the silicon-dioxide-containing liquid or highly viscous cover layer material in a particularly favorable and advantageous manner using a glass spin procedure so that the recesses 30, 31, 32 are completely filled with the cover layer 26 of silicon dioxide, and the substrate surface 22 is completely covered to form the essentially flat cover layer surface 27. Then the photodetector 20 can be completed using conventional CMOS procedures, e.g. doping by implanting ions, i.e., conventional semiconductor-forming steps.

In an alternative manufacturing method termed post-processing, the photodetector chips are manufactured using conventional CMOS technology. Then the passivation layer in the diode area made of silicon dioxide and silicon nitride is removed. Subsequently the peripheral dimensions of the recesses 30, 31, 32 are defined using prior-art photolithographic methods. Then the recesses 30, 31, 32 in the shape of the frustum of a pyramid 40 are created using an anisotropic etching procedure and then, as described above, are filled in or up with silicon dioxide to form the cover layer 26.

While there have been described and illustrated specific embodiments of the invention, it will be clear that variations in the details of the embodiments specifically illustrated and described may be made without department from the true spirit and scope of the invention as defined in the appended claims.

1. A photodetector for detecting electromagnetic waves comprising a substrate layer with at least one substrate surface, and at least one cover layer with a cover layer surface at least partially covering the substrate surface, the cover layer being transparent to the electromagnetic waves to be detected, the cover layer having an inhomogeneous thickness and sloping sides in a cross-sectional cut through the substrate layer.

2. The photodetector of claim I wherein the cover layer has a substantially saw-tooth shape in the cross-sectional cut through the substrate layer.

3. The photodetector of claim 1 wherein the cover layer has a substantially trapezoidal shape in the cross-sectional cut through the substrate layer.

4. The photodetector of claim 1 wherein the cover layer has a substantially V-shape in the cross-sectional cut through the substrate layer.

5. The photodetector of claim 1, wherein the substrate layer includes at least one recess

6. The photodetector of claim 5 wherein the cover layer includes at least one elevation.

7. The photodetector of claim 6 wherein the recess and the elevation are pyramidal in the cross sectional cut.

8. The photodetector of claim 7 wherein the recess and elevation have at least one flank that is essentially straight in the cross-sectional cut.

9. The photodetector of claim 1 wherein the substrate layer has at least one recess containing at least one flank that is essentially straight in the cross-sectional cut, and the cover layer surface is essentially flat.

10. The photodetector of claim 9 wherein the flank and the cover layer surface form an angle greater than 45°.

11. The photodetector of claim 9 wherein the flank and the cover layer surface form an angle of at least 54.7°.

12. The photodetector of claim 11 wherein at least two of the flanks oppose each other at an angle less than or equal to 70.6°.

13. The photodetector of claim 10 wherein at least two of the flanks oppose each other at an angle less than 90°.

14. The photodetector according to claim 1 wherein the cover layer thickness has an inhomogeneity of at least 0.5 micrometer.

15. The photodetector according to claim 1 wherein the cover layer thickness has an inhomogeneity of about 1 micrometer.

16. The photodetector of claim 1 wherein the electromagnetic wave s are UV waves and the substrate consists essentially of silicon.

17. A spectrometer for analyzing the spectral composition of electromagnetic waves from a sample, comprising a photodetector as in claim 1.

18. A photodiode array detector for analyzing the spectral composition of electromagnetic waves from a sample flowing through sample cell, comprising a plurality of photodetectors as in claim 1.

19. A method of making a photodetector for detecting electromagnetic waves as recited in claim 1 comprising anisotropically etching to form the at least one recess, filling the at least one recess with the cover layer so that the cross-section of the cover layer that penetrates the substrate layer is inhomogeneous and has the sloping side.

20. The method of claim 19 wherein the at least one recess is filled with the cover layer and the substrate surface is completely covered to form an essentially flat cover layer surface.

21. The method of claim 18 wherein the cover layer is applied as a flowing material to the substrate layer.

22. The method of claim 21 wherein the flowing material is a liquid.

23. The method of claim 21 wherein the flowing material is highly viscous.

24. The method of claim 21 wherein the flowing material is applied by a glass spin-on process.

25. The method of claim 19 further including performing semiconductor processing steps on the substrate after the at least one recess is formed.
